(19) United States
(12) Patent Application Publication
(10) Pub. No.: US 2004/0022944 A1
(43) Pub. Date: Feb. 5, 2004

(54) Method and device for blacking components

(76) Inventors: Wolfgang Lerche, Kleve (DE); Hansjakob Drissen, Bedburg-Hau (DE); Winfried Grafen, Duisburg (DE); Walter Ooster, Bedburg-Hau (DE)

Correspondence Address: CANTOR COLBURN LLP, 55 Griffin Road South, Bloomfield, CT, 06002, US

(21) Appl. No.: 10/632,037

(22) Filed: Jul. 30, 2003

(30) Foreign Application Priority Data
Aug. 1, 2002 (DE) 102 35 131.7

(51) Int. Cl. C23C 16/00

(52) U.S. Cl. 427/249.1; 427/294; 118/724

(57) ABSTRACT

The invention concerns a method for blacking components. In order to develop a method which creates black surfaces on components which are not inclined to peal off, and in which no fluids or baths are used which are expensive to produce, maintain or dispose of, it is proposed that the surfaces of the component are subjected to a heat treatment with simultaneous administration of a carbon-emitting medium inside the processing space. Furthermore, the invention concerns a device that can be operated using the method of the invention.

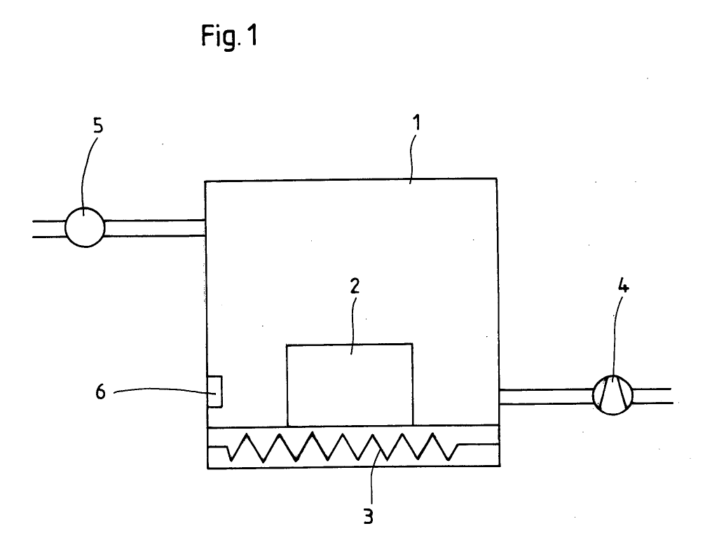

The invention concerns a method for blacking components. Furthermore, the invention concerns a device with which the method of the invention can be implemented.

Various methods for generating black surfaces are known from the state of the art. Here it is a matter of an oxidation method within gaseous atmospheres or liquid media as well as galvanic treatments. Black surfaces are generated in order, for example, to obtain an attractive surface of the component, to make the surface more corrosion resistant, for example, against film rust, and to obtain a higher resistance to abrasion.

A method for manufacturing uniform oxidation layers on metal workpieces in connection with a nitriding or nitrocarburizing method is known from EP 0 655 512 B1 in which the workpieces are exposed to an oxidation atmosphere for a specified time after nitriding or nitrocarburizing at a given temperature. During reoxidation, the outer edge layer of the workpiece, which basically consists of iron nitrides or carbon nitrides, is transformed in to a thin iron oxide layer. A layer of Fe₃O₄ is sought here. This layer has a black coloration. The disadvantage here is that the separate reprocessing represents an additional operation.

A method for treating parts, especially steel and/or cast parts, is known from DE 43 33 940 C1 in which a blacked surface is created in that the parts are simultaneously oxidized and hardened in a furnace using the introduction or injection of a reducing and oxidizing acting reaction gas at hardening temperatures. Here the disadvantage is that a stress on the furnace arises through the direct introduction in the hot state. Furthermore, a veil of flames must surround the part in order to prevent a premature oxidation during heating.

A further possibility for blacking surfaces consists in quenching the workpiece after tempering in an emulsion due to which the oxidized surface is blacked. Here the disadvantage is that an additional step must be performed. The emulsion must be protected against infestation with microbes, and it can only be disposed of by expensive treatment measures.

Reprocessing in liquids represents a further possibility for blacking the component surfaces. Here the components are dipped into so-called burnishing baths or salt baths after hardening. It is matter of additional steps in this process as well and the baths must be produced, monitored and eliminated at great expense. The problem is that they contain cyanides, in particular, in salt baths. Disposal is consequently costly and expensive.

A further possibility consists in galvanic solutions in electrolytic blacking. Here it is a question of black chromatin. But different colors can arise in this process on the basis of possible uneven layer thicknesses in metal precipitation. Furthermore, the disadvantage is that here an additional processing step is necessary and that the galvanic solution must be disposed of at great expense.

Generally the disadvantage in all oxide methods is that the oxide layers have an inclination to peel off if the oxide layer is too thick or there is not sufficient adhesion between oxide layer and surface. A greater layer of thickness can be necessary to obtain sufficient blacking.

Consequently the invention is based upon creating a process for blacking surfaces which creates black surfaces without an additional step with no tendency to peel off. No liquids or baths that are expensive to produce, maintain or dispose of are to be used. Furthermore, a device for implementing this method is to be created.

The realization of the objective in accordance with the invention provides that the surface is subjected to a heat treatment with simultaneous administration of a carbon-emitting medium within a treatment space. The surface of the component that is already situated within the treatment space is brought into contact with carbon. This occurs by the decomposition of the carbon-emitting medium. This takes place through the administration of heat. The carbon reacts with the surface of the component and blackens the latter.

Moreover, deep black surfaces are advantageously created while avoiding the previously cited disadvantages. With this method, in particular black surfaces can be created on tools that under certain circumstances have unattractive surfaces after hardening. Furthermore, the resistance to corrosion of the components can also be increased. Since the surfaces receive a “satin-like” luster, durable, decorative surfaces, for example for housings of stereo equipment or other metal parts which also have a design function in addition to functionality can be created.

An advantageous refinement of the invention provides that the heat treatment takes place at low temperatures. Moreover, a low pressure of 0.01 mbar to 100 mbar can be applied. Preferably the low pressure can move in a range from 0.1 mbar to 15 mbar. Low pressure makes possible a more favorable dosing of the carbon content in the furnace space, which prevents a sooting of the furnace space. At higher pressures, especially under atmospheric conditions, the dosable proportion of the carbon-emitting medium is too high, which unavoidably leads to a sooting of the furnace space in a disadvantageous manner. In this way, the costs for the carbon-emitting medium are also higher and the furnace must regularly be subjected to soot removal in order to guarantee optimal processing.

The heat treatment itself can be conducted at a temperature from 200° C. to 700° C. A good exchange of carbon with the surface of the component is reached in this temperature range. Preferably the temperature reaches 300° C. to 570° C., especially preferably from 350° C. to 475° C. Moreover, the duration of the heat treatment can regulated by a variation in temperature and/or pressure. The carbon content itself can be regulated inside the treatment space by a variation in pressure. The regulation can be necessary in order to reach a change of atmosphere in the treatment space through the duration of the treatment.

The carbon-emitting medium can be introduced into the treatment space in the form of a gas. Furthermore, a liquid feed is also possible. Hydrocarbons, especially acetylene, carbon monoxide or a mixture of them can be administered. These substances are suitable as a supplier of carbon owing to their good ability to decompose. But other substances are also conceivable as a carbon-emitting medium.

By reason of properties, no demands are to be placed upon the rate of cooling. For this reason, a cooling should be conducted as soon as possible at the end of the process due to plant availability.

The invention provides a device with a heatable processing space and a device for regulated administration of the carbon-emitting medium for implementing the process of the invention. The processing space can be evacuable. For evacuation of the processing space, a device, especially a vacuum pump, can be provided. Moreover, a monitoring device for the carbon content in the atmosphere can be provided in order to obtain a regulated administration of the carbon-emitting medium.

A furnace can be provided as a processing space. The furnace can have a liner. The liner can be made of metal. This must be dispensed with if catalytically acting surfaces are present. In such cases, the liner should not be metallic. Preferably, the liner can be constructed interchangeably in order to be able to eliminate any sooting.

The invention will be explained in greater detail below in a non-limiting manner on the basis of a drawing consisting of only one FIGURE.

The sole FIGURE illustrates a device of the invention in diagrammatic representation.

A component 2 is situated in a furnace chamber 1 of a vacuum furnace whose surface is to be blacked. The surfaces of the component 2 to be blacked are untreated. Using a heating unit 3, a temperature of 450° C. is generated in the furnace chamber 1. At the same time, the pressure in the furnace chamber 1 is reduced to a pressure of 5 mbar with a vacuum pump 4.

Acetylene (C₂H₂) is administered as a carbon-emitting medium to the furnace chamber 1 through a feeding unit 5. The acetylene is decomposed in the furnace chamber 1. Carbon is emitted to the atmosphere in furnace chamber 1. The carbon comes into contact with the surface of component 2 and brings about blacking.

The carbon content in the atmosphere in the furnace space 1 is monitored through a monitoring sensor 6. The monitoring sensor 6 controls the administration of the carbon-emitting medium through a connection (not represented) in order to be able to set an optimal concentration. The carbon content is set such that a sooting of the furnace chamber walls is avoided as far as possible. Toward the end of the processing time, the administration of acetylene is reduced in order to obtain an optimal exploitation of the carbon. After a processing time of two hours, the remaining atmosphere is sucked off and ambient pressure is restored in the furnace chamber. Moreover, the furnace space and the component 2 are immediately cooled off as rapidly as possible so that the device is available for the next process that does not have any consequent changes in properties on the blacked component 2. Subsequently, the component 2 with blacked surface can be removed from the furnace chamber 1. The surface black coloration generated in this way adheres fast, which can be demonstrated using an abrasion test.

Reference number list

| | |
|---|---|
| 1 | Furnace chamber |
| 2 | Component |
| 3 | Heating unit |
| 4 | Vacuum pump |
| 5 | Feeder unit |
| 6 | Monitoring sensor |

1. Method for blacking components, characterized in that the surface is subjected to a heat treatment with simultaneous administration of a carbon-emitting medium inside a processing space (1).

2. Method according to claim 1, characterized in that the heat treatment takes place at low pressure.

3. Method according to claim 1 or 2, characterized in that a low pressure from 0.01 mbar to 100 mbar is applied.

4. Method according to claim 3, characterized in that preferably a low pressure from 0.1 mbar to 15 mbar is applied.

5. Method according to one of claims 1 to 4, characterized in that the heat treatment is conducted at a temperature from 200° C. to 700° C.

6. Method according to claim 5, characterized in that preferably the heat treatment is conducted at a temperature from 300° C. to 570° C.

7. Method according to claim 5, characterized in that the heat treatment especially preferably takes place at a temperature from 350° C. to 475° C.

8. Method according to one of claims 1 to 7, characterized in that a regulation of the processing time takes place as a function of temperature and/or pressure.

9. Method according to one of claims 1 to 8, characterized in that the carbon content is regulated inside the processing space as a function of temperature.

10. Method according to one of claims 1 to 9, characterized in that the carbon-emitting medium is administered in the form of a gas.

11. Method according to one of claims 1 to 9, characterized in that the carbon-emitting medium is administered in the form of a liquid.

12. Method according to one of claims 1 to 11, characterized in that hydrocarbons, especially acetylene and/or carbon monoxide are administered as a carbon-emitting medium.

13. Device for implementing the method according to claims 1 to 12 with a heatable processing space (1) and a device for regulated feeding (5) of the carbon-emitting medium.

14. Device according to claim 13, characterized in that the processing space (1) is evacuable.

15. Device in accordance with claim 14, characterized in that a vacuum pump (4) is provided for evacuation.

16. Device in accordance with one of claims 12 to 15, characterized in that a monitoring device (6) for the carbon content in the atmosphere of the processing space (1) is provided for regulated feeding of the carbon-emitting medium.

17. Device in accordance with one of claims 12 to 16, characterized in that the processing space (1) is a furnace.

18. Device in accordance with claim 17, characterized in that the furnace has a liner.

19. Device according to claim 18, characterized in that the liner is interchangeable.
